(19) United States
(12) Patent Application Publication
(10) Pub. No.: US 2007/0189956 A1
(43) Pub. Date: Aug. 16, 2007

(54) Method for producing a monocrystalline cu(in,ga)se2powder, and mono-grain membrane solar cell containing said powder

(75) Inventors: Volker Geyer, Niederkruechten (DE); Mare Altosaar, Tallinn (EE); Enn Mellikov, Saku (EE); Jaan Raudoja, Tallinn (EE)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Scheuten Glasgroep, Venlo (NL)

(21) Appl. No.: 10/582,464

(22) PCT Filed: Nov. 30, 2004
(86) PCT No.: PCT/EP04/13568

§ 371 Date: Feb. 22, 2007

(30) Foreign Application Priority Data
Dec. 22, 2003 (EP) 03029576.0

(51) Int. Cl. C01B 19/00; C30B 21/02; C30B 17/00; H01L 31/042; C30B 9/00; H02N 6/00; C01B 25/14; C30B 28/06; C30B 11/00

(52) U.S. Cl. 423/508; 117/73; 136/251

(57) ABSTRACT

A method for producing a powder of a Cu(In,GA)Se₂ compound, including the following steps: Cu and In and/or Cu and Ga are alloyed to form a CuIn and/or CuGa alloy with a substoichiometric content of Cu; producing a powder of the CuIn and/or CuG alloy; Se and either KI or NaI are added to the powder, the mixture is heated until a melted mass is formed, in which the Cu(In,Ga)Se₂ compound recrystallizes, and the powder grains to be produced simultaneously grow; and the melted mass is cooled in order to interrupt the growth of the grains. The invention also relates to a monogram membrane solar cell containing a back contact, a monogram membrane containing a powder produced by the inventive method, at least one semiconductor layer, and a front contact.

The invention relates to a method for the production of mono-crystalline powder consisting of a Cu(In,Ga)Se₂ compound. The invention also relates to the use of a powder produced with the method.

Such powders are especially well-suited for the production of mono-particle membranes that are used in solar cells.

International patent application WO 99/67449 describes a method of this generic type for the production of mono-crystalline powder consisting of semiconductor material, with which powder particles of CuInSe₂ can be produced. With this method, the components of the semiconductor material are melted in a stoichiometric composition, a fluxing agent is added and the melt with the fluxing agent is brought to a temperature at which the powder crystallizes out and the powder particles grow. NaCl, Se, As, arsenides or selenides can be used as the fluxing agent.

The invention is based on the objective of refining a method of the generic type in such a way that the properties of the powder particles are improved with an eye towards their use in a solar cell.

It is also the objective of the invention to create a mono-particle membrane solar cell with the highest possible efficiency factor.

In terms of the method, this objective is achieved according to the invention by a method for the production of a powder consisting of a Cu(In,Ga)Se₂ compound, said method comprising the following steps:
alloying Cu and In and/or Cu and Ga to form a CuIn and/or CuGa alloy with a sub-stoichiometric fraction of Cu,
producing a powder consisting of the CuIn and/or CuGa alloy,
adding Se as well as either KI or NaI to the powder,
heating up the mixture until a melt is formed in which the Cu(In,Ga)Se₂ recrystallizes and, at the same time, the powder particles to be produced grow,
cooling off the melt in order to interrupt the growth of the particles.

The method according to the invention leads to the surprising effect that the particles produced with this method have considerably improved photovoltaic properties in comparison to those produced with the known method according to the state of the art.

Solar cells employing the powder produced by means of the method according to the invention achieved a considerably higher efficiency factor.

This could be due to the following reasons:

With the known method according to the state of the art, due to the use of a stoichiometric amount of Cu relative to the CuInSe₂ to be prepared, the problem could arise that powder particles having a high content of Cu could be formed. In these particles, a phase segregation into stoichiometric CuInSe₂ and a metallic CuSe binary phase could occur, whereby this foreign phase tends to accumulate on the surface of the particles, markedly impairing the properties of a solar cell. Thus, for example, a short circuit in the p-n contact of the cell can occur.

Moreover, with the known method, CuSe phases formed during the production tend to be deposited on the particles. It is known that these phases can be washed out with a KCN solution; however, this solution attacks the particles themselves.

It is suspected that, in contrast, the use of a sub-stoichiometric amount of Cu relative to the compound to be produced as is done in the method according to the invention causes the formation of particles having a high content of Cu to be largely suppressed so that primarily powder particles having a low content of Cu are formed, which are suitable for the production of high-efficiency solar cells.

Moreover, it is assumed that the binary CuSe phases formed during the production of the particles remain in the fluxing agents Kl and NaI employed according to the invention and that they are not deposited on the particles.

This seems to be the case especially when the melt is cooled off very rapidly, that is to say, when this is done in the form of quenching. Another advantage of the method according to the invention is that the fluxing agent can be dissolved out with water, which does not attack the particles themselves.

Therefore, in a preferred implementation of the method according to the invention, after the melt has cooled off, the Kl or NaI is removed from the cooled-off melt by being dissolved out with water.

It is also very advantageous for the ratio of the molar amount of Cu employed to the sum of the molar amount of In employed plus the molar amount of Ga employed to lie between 0.8 and 1.

It has turned out that powder particles having this ratio of the molar amount of Cu to the molar amount of In and Ga can be used to produce solar cells that achieve an especially high efficiency factor.

It is also provided for the ratio of the molar amount of Ga employed to the molar amount of In employed to lie between 0 and 0.43. In this context, a ratio of 0.43 corresponds to approximately a Ga fraction of 30% relative to the molar amount of In and Ga.

The band gap energy of the Cu(In,Ga)Se₂ semiconductor compound varies with the ratio of the amount of In employed to the amount of Ga employed and, on the basis of the possible values of this In:Ga ratio, the band gap energy of the semiconductor material can be readily adapted to the desired application purpose.

Moreover, within the scope of the invention, an advantageous solar cell can be created.

In particular, this is a mono-particle membrane solar cell, comprising a back contact, a mono-particle membrane, at least one semiconductor layer and a front contact, which is characterized in that the mono-particle membrane contains the powder produced according to the invention.

A few preferred implementations of the method and preferred embodiments of the solar cell powder will be presented in detail below.

First of all, Cu and In and/or Cu and Ga are alloyed, whereby the molar amounts of Cu employed on the one hand and of In and Ga on the other hand are selected in such a way as to form CuIn and CuGa alloys having low contents of Cu. It has proven to be especially advantageous in the production of powder particles employed in solar cells for the Cu:(In+Ga) ratio, that is to say, the ratio of the molar amount of Cu employed to the sum of the molar amount of In employed and the molar amount of Ga employed, to lie between 1 and 1:1.2.

The ratio of the molar amount of Ga employed to the molar amount of In employed is preferably between 0 and 0.43. In this context, a ratio of 0.43 corresponds approximately to a Ga fraction of 30% relative to the molar amount of In and Ga. Thus, with the method according to the invention, preferably those Cu(In,Ga)Se₂ compounds are produced whose molar ratio of Ga to In lies between this molar ratio of the compounds CuInSe₂ and CuGa_{0.3}In_{0.7}Se₂.

The alloys are then ground up into a powder, whereby it has been found that the particle sizes of the Cu(In,Ga)Se₂ powder particles to be produced depend on the particle size of the powder made from the CuIn and/or CuGa alloy. Hence, powders are ground systematically so as to contain particles of a specific size.

The powder consisting of the alloys CuIn and CuGa is now filled into an ampoule that is made of a material that does not react with any of the substances that are to be placed into it. Thus, it is made, for example, of quartz glass.

Se is added to the powder in an amount that corresponds to the stoichiometric fraction of this element in the Cu(In,Ga)Se₂ compound that is to be produced.

Furthermore, either Kl or NaI is added as the fluxing agent, whereby the fraction of the fluxing agent in the melt that is subsequently formed is typically about 40 vol.-%. In general, however, the fraction of the fluxing agent in the melt can be between 10 vol.-% and 90 vol.-%.

The ampoule is now evacuated and heated with the indicated content to a temperature between 650° C. and 810° C. [1202° F. and 1490° F.]. Cu(In,Ga)Se₂ is formed during the heating process.

Once a temperature within the above-mentioned temperature range is reached, Cu(In,Ga)Se₂ recrystallizes and, at the same time, the particles grow.

The fluxing agent will have melted at this temperature, so that the space between the particles is filled with a liquid phase that serves as a transport medium.

The melt is kept constant at the pre-set temperature during a certain holding time. Depending on the desired particle size, a holding time between 5 minutes and 100 hours can be required. Typically, this is about 30 hours.

The growth of the particles is interrupted by cooling off the melt. Here, it is very advantageous to quench the melt very rapidly, for example, within just a few seconds.

This so-called quenching seems to be necessary so that any binary CuSe phases that might have formed will remain in the fluxing agent.

If the cooling off is carried out slowly, the risk probably exists that the CuSe phases will be deposited onto the Cu(In,Ga)Se₂ crystals, markedly impairing the properties of the produced powder in terms of its use in solar cells.

In a last step of the method, the fluxing agent is removed by dissolving it out with water. The mono-crystalline powder particles can then be taken out of the ampoule.

The suitable temperature course over time during the heating up and cooling off as well as the holding time and the temperature to be maintained during the holding time are determined in preliminary experiments.

Using the method described, powders can be produced whose individual particles have a mean diameter of 0.1 μm to 0.1 mm. The particle size distribution within the powder corresponds to a Gauss distribution along the lines of D=A·t^{1/n}·exp(−E/kT), wherein D is the particle diameter, t is the holding time and T is the temperature of the melt; k, as usual, stands for the Boltzmann constant. The parameters A, n and E depend on the starting substances employed, on the fluxing agent and on the specific growth processes, which are not described in greater detail here. If Kl is used as the fluxing agent, then E equals approximately 0.25 eV. In this case, the value for n is between 3 and 4.

The mean particle size and the precise shape of the particle size distribution depend on the holding time, on the temperature of the melt and on the particle size of the employed powder consisting of the CuIn and CuGa alloys. Moreover, the mean particle size and particle size distribution are influenced by the choice of the fluxing agent.

The particles that can be produced with the method according to the invention are p-conductive and exhibit a very good electric conductivity. The electric resistances of the produced Cu(In,Ga)Se₂ powder particles were in a range from 100 Ω to 10 kΩ, depending on the Cu:Ga ratio selected, on the Cu:(In+Ga) ratio and on the temperature of the melt. This corresponds to a specific resistance of 10 kΩcm to 2 MΩcm.

By using the method according to the invention, it was possible to produce mono-crystalline powders whose particles display a very uniform composition.

The powders are especially well-suited for the production of mono-particle membranes that are used in solar cells, whereby, using powders made with the method according to the invention, it was possible to make solar cells having a very high efficiency factor.

Especially in view of the possible application purposes of the powder produced with the method according to the invention, it should be pointed out that it is also fundamentally possible to add S, in addition to the Se, to the powder consisting of the CuIn and/or CuGa and to melt it together with the fluxing agent. By the same token, the Se can be completely replaced with S.

Consequently, the method makes it possible to produce a wide range of CuInₗ₋ₓGaₓS_{y}Se_{z} compounds. These semiconductor compounds cover a range of band gap energies between 1.04 eV and 2.5 eV.

It has been found that the powders produced with the method presented can be used very advantageously in solar cells. The solar cells in which these powders were used exhibited an above-average high efficiency factor.

The solar cells in which powders produced according to the invention are used are preferably solar cells into which a mono-particle membrane made of the powder is incorporated.

In order to produce the mono-particle membrane, the powder particles are preferably embedded into a polymer membrane, especially a polyurethane matrix.

A mono-particle membrane solar cell normally consists of four layers.

The back contact is a metallic layer that is typically applied onto a glass substrate. In a preferred embodiment, this can also be an electrically conductive adhesive.

The membrane containing the Cu(In,Ga)Se₂ crystals is applied as an absorber layer onto this back contact and this membrane is normally covered with a thin, n-conductive CdS semiconductor layer.

The front contact is then applied onto this CdS layer and it normally consists of a transparent, electrically conductive oxide, for example, a ZnO:Al alloy.

It can likewise be very preferred to incorporate another semiconductor layer made of intrinsic ZnO between the CdS layer and the front contact.

1. A method for the production of a powder consisting of a Cu(In,Ga)Se₂ compound, comprises the following steps:
alloying Cu and at least one of In and Ga to form at least one of a CuIn alloy and a CuGa alloy with a sub-stoichiometric fraction of Cu,
producing a powder of the alloy,
adding Se and a KI or NaI fluxing agent to the powder,
heating the mixture until a melt is formed in which Cu(In,Ga)Se₂ recrystallizes and, at the same time, the powder particles to be produced grow,
cooling the melt in order to interrupt the growth of the particles.

2. The method according to claim 1, comprising,
after the cooling step, removing the KI or NaI by dissolution with water.

3. The method according to claim 1,
wherein
the ratio of the molar amount of Cu employed to the sum of the molar amount of In employed plus the molar amount of Ga employed lies between 0.8 and 1.

4. The method according to claim 1,
wherein
the ratio of the molar amount of Ga employed to the molar amount of In employed lies between 0 and 0.43.

5. A mono-particle membrane solar cell, comprising a back contact, a mono-particle membrane, at least one semiconductor layer and a front contact,
wherein
the mono-particle membrane contains a powder produced by a method according to claim 1.
